(19) United States
(12) Patent Application Publication
(10) Pub. No.: US 2009/0278187 A1
(43) Pub. Date: Nov. 12, 2009

(54) SEMICONDUCTOR DEVICE AND MANUFACTURING METHOD OF SEMICONDUCTOR DEVICE

(76) Inventor: Takayuki TOBA, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/406,481

(22) Filed: Mar. 18, 2009

(30) Foreign Application Priority Data
May 9, 2008 (JP) 2008-123904

(51) Int. Cl. H01L 29/788; H01L 21/336; H01L 29/792

(52) U.S. Cl. 257/316; 438/257; 257/324; 257/E29.3; 257/E29.309; 257/E21.422

(57) ABSTRACT

A semiconductor device of an aspect of the present invention includes a semiconductor substrate, two diffusion layers provided in the semiconductor substrate, a gate insulating film provided on a channel region between the two diffusion layers, and a gate electrode which is composed of a stack of a plurality of conductive films and a plurality of insulating films provided on the gate insulating film and a silicide layer provided on the stack, wherein of the plurality of films included in the stack, the conductive film different in configuration from the silicide layer is in contact with the gate insulating film.

### CROSS-REFERENCE TO RELATED APPLICATIONS

This application is based upon and claims the benefit of priority from prior Japanese Patent Application No. 2008-123904, filed May 9, 2008, the entire contents of which are incorporated herein by reference.

### BACKGROUND OF THE INVENTION

1. Field of the Invention

The present invention relates to a semiconductor device, and more particularly, it relates to a MIS transistor and a semiconductor memory with the MIS transistor. The present invention also relates to manufacturing methods of these semiconductor devices.

2. Description of the Related Art

In a semiconductor integrated circuit, a metal-insulator-semiconductor (MIS) transistor is provided as one component. Recently, for improvement in element characteristics, there have been developed a MIS transistor employing a high dielectric gate insulating film and a metal gate structure, and a MIS transistor employing a strained Si technique.

In a nonvolatile semiconductor memory such as a flash memory, the MIS transistor is mainly provided in a peripheral circuit region located around a memory cell array region, as an element for controlling the operation in the memory cell array region.

A gate electrode of a memory cell in the memory cell array region functions as a word line as well, and a reduction of its resistance is therefore desired. Thus, what is called a fully-silicided (FUSI) structure in which a polysilicon film is fully silicided is used for the gate electrode of the memory cell.

In order to simplify the manufacturing process of the flash memory, the memory cell and the MIS transistor are formed in a common manufacturing process (e.g., refer to Jpn. Pat. Appln. KOKAI Publication No. 7-183411). As a result, gate electrode materials formed in the peripheral circuit region and the memory cell array region are equal in thickness. Therefore, if the gate electrode of the memory cell is formed into the FUSI structure by silicidation (silicidation processing) based on a solid-phase reaction between polysilicon and a metal, the gate electrode of the MIS transistor is also formed into the FUSI structure.

When the gate electrode of the MIS transistor has the FUSI structure, despite the fact that a plurality of elements may have equal characteristics, differences in threshold voltage may still exist between such elements due to nonuniformity of a silicide layer. This disadvantageously leads to instability both in the operation of a MIS transistor having a FUSI structure gate electrode of the FUSI structure and the operation of the flash memory with such MIS transistor.

### BRIEF SUMMARY OF THE INVENTION

A semiconductor device of an aspect of the present invention comprising: a semiconductor substrate; two diffusion layers provided in the semiconductor substrate; a gate insulating film provided on a channel region between the two diffusion layers; and a gate electrode which is composed of a stack of a plurality of conductive films and a plurality of insulating films provided on the gate insulating film and a silicide layer provided on the stack, wherein of the plurality of films included in the stack, the conductive film different in configuration from the silicide layer is in contact with the gate insulating film.

A manufacturing method of a semiconductor device of an aspect of the present invention comprising: forming a gate insulating film on a semiconductor substrate; forming a stack of a plurality of conductive films and a plurality of insulating films on the gate insulating film; forming a silicon layer on the stack; etching the silicon layer and the stack to gate electrode fabrication; forming a diffusion layer in the semiconductor substrate after the gate electrode fabrication; forming a metal film on the silicon layer; and forming a silicide layer on the stack by a solid-phase reaction between the silicon layer and the metal film so that the conductive film in contact with the gate insulating film of the plurality of conductive films included in the stack is not silicided.

A semiconductor device of an aspect of the present invention comprising: a semiconductor substrate; a memory cell array region provided in the semiconductor substrate; a memory cell having two first diffusion layers which are provided in the semiconductor substrate within the memory cell array region, a tunnel insulating film provided on a channel region between the first diffusion layers, a storage layer provided on the tunnel insulating film, an intermediate insulating layer provided on the storage layer, and a first gate electrode which is provided on the intermediate insulating layer and which is formed of a first silicide layer; a peripheral circuit region provided in the semiconductor substrate adjacently to the memory cell array region; and a peripheral transistor having two second diffusion layers provided in the semiconductor substrate within the peripheral circuit region, a gate insulating film provided on a channel region between the second diffusion layers, and a second gate electrode which is composed of a stack of a plurality of conductive films and a plurality of insulating films provided on the gate insulating film and a second silicide layer provided on the stack, wherein the conductive film different in configuration from the second silicide layer of the plurality of conductive films included in the stack is in contact with the gate insulating film.

### BRIEF DESCRIPTION OF THE SEVERAL VIEWS OF THE DRAWING

FIG. 1 is a sectional view showing the structure of a MIS transistor according to a first embodiment;

FIG. 2 is a sectional view showing the structure of the MIS transistor according to the first embodiment;

FIG. 3 is a sectional view showing the structure of the MIS transistor according to the first embodiment;

FIG. 4 is a diagram showing one step of a manufacturing method of the MIS transistor according to the first embodiment;

FIG. 5 is a diagram showing one step of the manufacturing process of the MIS transistor according to the first embodiment;

FIG. 6 is a diagram showing one step of the manufacturing process of the MIS transistor according to the first embodiment;

FIG. 7 is a diagram showing one step of the manufacturing process of the MIS transistor according to the first embodiment;

FIG. 8 is a schematic diagram showing the overall configuration of a nonvolatile semiconductor memory according to a second embodiment;

FIG. 9 is a plan view showing the structure of the flash memory according to the second embodiment;

FIG. 10 is a sectional view showing the structure of the flash memory according to the second embodiment;

FIG. 11 is a sectional view showing the structure of the flash memory according to the second embodiment;

FIG. 12 is a sectional view showing the structure of the flash memory according to the second embodiment;

FIG. 13 is a sectional view showing the structure of the flash memory according to the second embodiment;

FIG. 14 is a sectional view showing one step of a manufacturing process of the flash memory according to the second embodiment;

FIG. 15 is a sectional view showing one step of the manufacturing process of the flash memory according to the second embodiment;

FIG. 16 is a sectional view showing one step of the manufacturing process of the flash memory according to the second embodiment;

FIG. 17 is a sectional view showing one step of the manufacturing process of the flash memory according to the second embodiment;

FIG. 18 is a sectional view showing one step of the manufacturing process of the flash memory according to the second embodiment;

FIG. 19 is a sectional view showing the structure of a flash memory according to a modification of the second embodiment; and

FIG. 20 is a sectional view showing the structure of the flash memory according to the modification of the second embodiment.

### DETAILED DESCRIPTION OF THE INVENTION

Some embodiments of the present invention will hereinafter be described in detail with reference to the drawings.

### 1. Embodiments

Semiconductor devices according to the embodiments of the present invention are a MIS transistor and a semiconductor integrated circuit with the MIS transistor. The structure of the MIS transistor and its manufacturing method will be described below in one embodiment of the present invention. A nonvolatile semiconductor memory as an example of a semiconductor circuit using the MIS transistor and its manufacturing method will be described below in another embodiment of the present invention.

### [1] First Embodiment

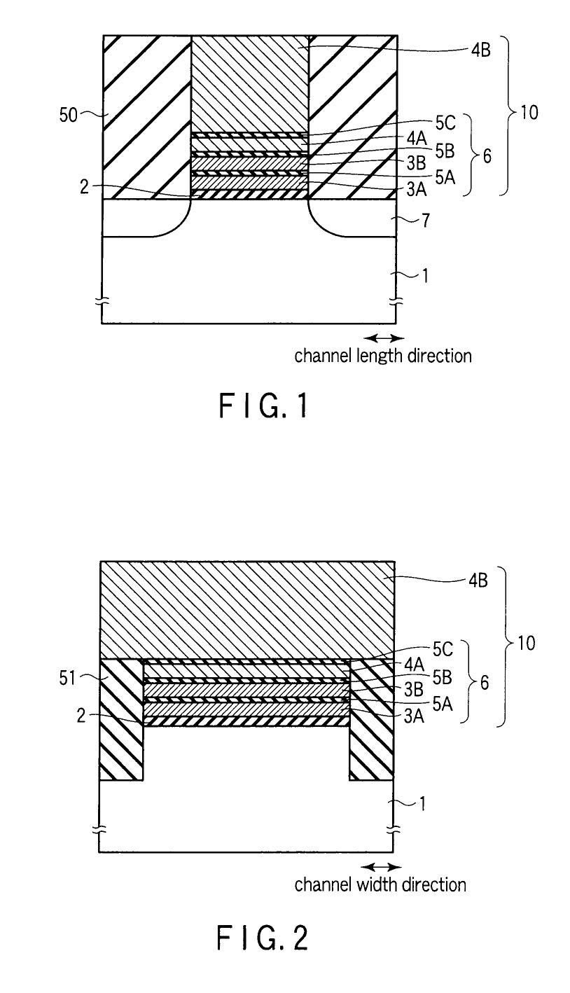

A first embodiment of the present invention is described with reference to FIGS. 1 to 7.

(1) Structure

The structure of a semiconductor device (MIS transistor) according to one embodiment of the present invention is described with reference to FIGS. 1 and 2. FIG. 1 shows the sectional structure of the MIS transistor according to the present embodiment in a channel length direction. FIG. 2 shows the sectional structure of the MIS transistor according to the present embodiment in a channel width direction.

As shown in FIGS. 1 and 2, the MIS transistor comprises two diffusion layers 7 provided in a semiconductor substrate (e.g., a silicon substrate) 1, a gate insulating film 2 provided on the surface of the semiconductor substrate 1 between the two diffusion layers 7, and a gate electrode 10 provided on the gate insulating film 2. The gate electrode 10 is covered with an interlayer insulating film 50.

The two diffusion layers 7 function as source/drain regions. A channel region is formed between the two diffusion layers 7, and the gate insulating film 2 is provided on the surface of the semiconductor substrate 1 in the channel region. The diffusion layers functioning as the source/drain regions are hereinafter referred to as source/drain diffusion layers.

The gate electrode 10 is provided on the gate insulating film 2, and includes a stack 6 in which a plurality of conductive films 3A, 3B, 4A and a plurality of insulating films 5A, 5B, 5C are alternately stacked, and a silicide layer 4B provided on the stack 6. In addition, although three conductive films and three insulating films are shown in the stack 6 in FIGS. 1 and 2, these films are not limited to this number.

For example, the conductive films and the insulating films are sequentially stacked in the stack 6 so that the conductive film 3A is in direct contact with the gate insulating film 2.

The plurality of insulating films 5A, 5B, 5C constituting the stack 6 are insulating films having an extremely small thickness, and are made of, for example, silicon oxide films having a thickness of 2 nm or less.

Of the plurality of conductive films constituting the stack 6, the conductive film 3A on the lower end of the stack 6 (on the side of the gate insulating film 2) is made of a conductive material different from the material of the silicide layer 4B, such as polysilicon. Further, a conductive film 4A on the upper end of the stack 6 (on the side of the silicide layer 4B) is made of a conductive material different from the material of the conductive film 3A. For example, the conductive film 4A is made of the same silicide material as the silicide layer 4B. The conductive film 3B between the conductive film 3A and the conductive film 4A is either a polysilicon film or a silicide film. Hereinafter, the conductive film 3A is also referred to as a polysilicon film 3A, and the conductive film 4A is also referred to as a silicide film 4A.

For example, nickel silicide (NiSi₂) is used for the silicide layer 4B. In addition, the silicide layer 4B is not limited to NiSi₂, and one of cobalt silicide (CoSi₂), titanium silicide (TiSi₂), tungsten silicide (WSi₂) and molybdenum silicide (MoSi₂) may be used for the silicide layer 4B. NiSi₂ is used for the silicide layer 4B in the example described below.

As shown in FIG. 2, an isolation insulating film 51 is provided in the semiconductor substrate 1. Adjacent element regions are electrically separated from each other by the isolation insulating film 51. The upper surface of the isolation insulating film 51 is formed to coincide with, for example, the upper surface of the insulating film 5C provided in the uppermost layer of the stack 6. The position of the upper surface of the isolation insulating film 51 is thus equal to the position of the insulating film 5C, such that a large distance between the silicide layer 4B and the semiconductor substrate 1 is ensured, and the formation of a channel (inversion layer) at the bottom of the isolation insulating film 51 can be prevented.

The MIS transistor according to the embodiment of the present invention is characterized in that the gate electrode 10 is composed of the stack 6 and the silicide layer 4B, and in that, of the conductive films 3A, 3B, 4A included in the stack 6, the conductive film 3A made of a material (e.g., polysilicon) different from the material of the silicide layer 4B is in contact with the gate insulating film 2.

In the MIS transistor shown in FIGS. 1 and 2, instead of a FUSI structure in which the whole gate electrode 10 serves as the silicide layer 4B, the conductive film 3A in contact with the gate insulating film 2 is made of a conductive material different from the material of the silicide layer 4B, such as the polysilicon film 3A.

Although its specific formation method is described in detail later, the insulating films 5A, 5B, 5C included in the stack function as stopper films (filters) for inhibiting the diffusion of atoms of a metal material (e.g., nickel) that forms the silicide film 4A, during the formation of the silicide layer 4B.

The polysilicon films and the silicon oxide films are alternately stacked in the stack 6. The silicide layer 4B is formed by a solid-phase reaction between the polysilicon film deposited on the stack 6 and the nickel film. In this case, of the plurality of conductive films constituting the stack 6, the conductive film 4A on the side of the silicide layer 4B is not prevented enough from the diffusion of metal atoms because one insulating film 5C is only interposed between the silicide layer 4B and the conductive film 4A. Thus, the conductive film 4A is partly silicided and becomes a silicide film 4A.

On the other hand, of the plurality of conductive films constituting the stack 6, the conductive film 3A on the immediate gate insulating film 2 is made of, for example, a polysilicon film 3A. The reason for this is that a plurality of insulating films 5A, 5B, 5C are interposed between the conductive film 3A and the silicide layer 4B, so that the number of Ni atoms diffusing in the stack 6 gradually decreases toward the gate insulating film 2 and the conductive film 3A is not silicided.

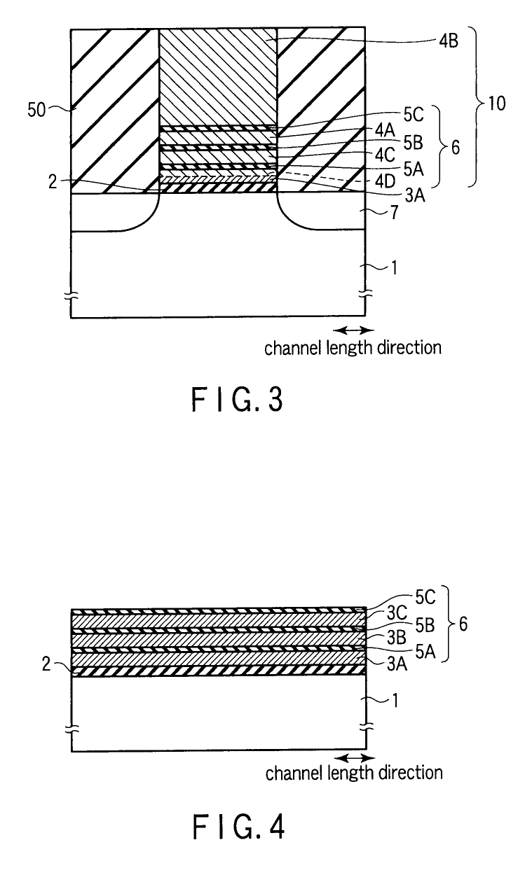

Furthermore, as mentioned above, the number of Ni atoms diffusing in the stack 6 gradually decreases toward the gate insulating film 2. Thus, the composition ratio (Ni/Si) of the Ni (metal) atoms to Si atoms is higher in the conductive film located on the side of the silicide layer 4B of the plurality of conductive films included in the stack 6, and the composition ratio of the Ni (metal) atoms to Si atoms is lower in the conductive film located on the side of the gate insulating film 2. That is, each of the plurality of conductive films in the stack 6 has a different composition ratio between Ni and Si. Therefore, in the conductive film 3B between the conductive film 3A, and the silicide film 4A included in the stack 6, the composition ratio of the Ni atoms to the Si atoms in the conductive film 3B is equal to or higher than that in the conductive film 3A and is equal to or lower than that in the silicide film 4A. Thus, in the plurality of conductive films constituting the stack 6, the number of Ni (metal) atoms contained in the conductive film on the side of the gate electrode (silicide film 4A) is greater than the number of Ni (metal) atoms contained in the conductive film on the side of the gate insulating film. In addition, it is only necessary for the part of the conductive film 3A in immediate contact with the gate insulating film 2 not to be a silicide film. For example, as shown in FIG. 3, part of the conductive film 3A on the side of the silicide layer 4B may be silicided so that the lowermost conductive film of the stack 6 has a partial structure composed of a silicide part 4D and a polysilicon part 3A.

Consequently, in the present embodiment, the difference in work function between the semiconductor substrate (e.g., silicon substrate) and the gate electrode is determined by, for example, the silicon substrate and the uniform polysilicon film, and the threshold voltage of the MIS transistor is defined on the basis of the difference in work function. Therefore, there is almost no variation in the threshold voltage of the MIS transistor due to nonuniformity of the silicide layer in direct contact with the gate insulating film 2. As a result, it is possible to inhibit an element-by-element variation in the threshold voltage of the MIS transistor due to the nonuniformity of the silicide layer included in the gate electrode.

Furthermore, the gate electrode 10 of the MIS transistor includes the silicide layer and is thus reduced in resistance.

In the present embodiment, while the stack 6 forming the gate electrode 10 of the MIS transistor includes the plurality of insulating films 5A, 5B, 5C, the physical thickness of even the insulating films 5A, 5B, 5C which inhibit the passage of the Ni atoms (metal atoms) is smaller than the thickness of the gate insulating film 2. The physical thickness of the insulating films 5A, 5B, 5C is equal to or less than, for example, 2 nm, and is extremely small. Therefore, when the MIS transistor in the present embodiment is driven, a drive voltage applied to the gate electrode 10 is provided between the silicide layer 4B and the polysilicon film 3A formed on the upper surface of the gate insulating film 2 with a small potential drop. Thus, a channel (inversion layer) is formed in the semiconductor substrate 1 under the gate insulating film 2, so that the operation of the MIS transistor is not interrupted by the stack 6 including the plurality of insulating films.

As described above, in the MIS transistor according to the first embodiment of the present invention, the gate electrode 10 is composed of the stack 6 provided on the gate insulating film 2 and including the plurality of conductive films 3A, 3B, 4A and the plurality of insulating films 5A, 5B, 5C, and the silicide layer 4A provided on the stack 6. Moreover, in the stack 6, the conductive film 3A in contact with the gate insulating film 2 uses a material different from the material of the silicide layer 4A and a material which a difference in work function to a substrate is small, such as polysilicon to Si substrate.

Thus, the stack 6 including the extremely thin insulating films is provided on the gate insulating film 2, such that the gate electrode 10 of the MIS transistor does not have a FUSI structure, and it is possible to prevent a variation in the threshold voltage of the MIS transistor due to the nonuniformity of the silicide layer on the immediate gate insulating film 2.

Therefore, it is possible to inhibit any element-by-element variation in the threshold voltage in the MIS transistor and in a semiconductor integrated circuit having a plurality of MIS transistors.

Consequently, according to the first embodiment of the present invention, it is possible to eliminate any instability in the operation of the semiconductor device caused by the variation in the threshold voltage.

(2) Manufacturing Method

The manufacturing method of the MIS transistor according to the embodiment of the present invention is described with FIGS. 1, 4 to 7. It should be noted that only the sectional structure of the MIS transistor in the channel length direction is described here.

As shown in FIG. 4, a silicon oxide film, for example, is formed as a gate insulating film 2 on a semiconductor substrate 1 (e.g., silicon substrate) by a thermal oxidation method. In addition, the gate insulating film 2 is not limited to a silicon oxide film, and may be, for example, a stack film of a silicon oxide film and a silicon nitride film, or a high dielectric gate insulating film of, for example, Al₂O₃, HfO₂, Ta₂O₅, La₂O₃, LaLiO₃, ZrO₂, Y₂O₃ or ZrSiO₄.

Then, a plurality of conductive films 3A, 3B, 3C and a plurality of insulating films 5A, 5B, 5C are alternately deposited on the gate insulating film 2, thereby forming a stack 6. The plurality of conductive films 3A, 3B, 3C are, for example, polysilicon films, and are formed by a chemical vapor deposition (CVD) method to have a thickness of about 10 nm to 15 nm. The plurality of insulating films 5A, 5B, 5C are, for example, silicon oxide films formed by the thermal oxidation method. The thickness of the silicon oxide film is, for example, about 1 nm to 2 nm. In addition, the plurality of insulating films 5A, 5B, 5C may otherwise be native oxide films formed on the polysilicon films. Moreover, it is preferable to form the stack 6 so that the conductive film may be in direct contact with the gate insulating film 2.

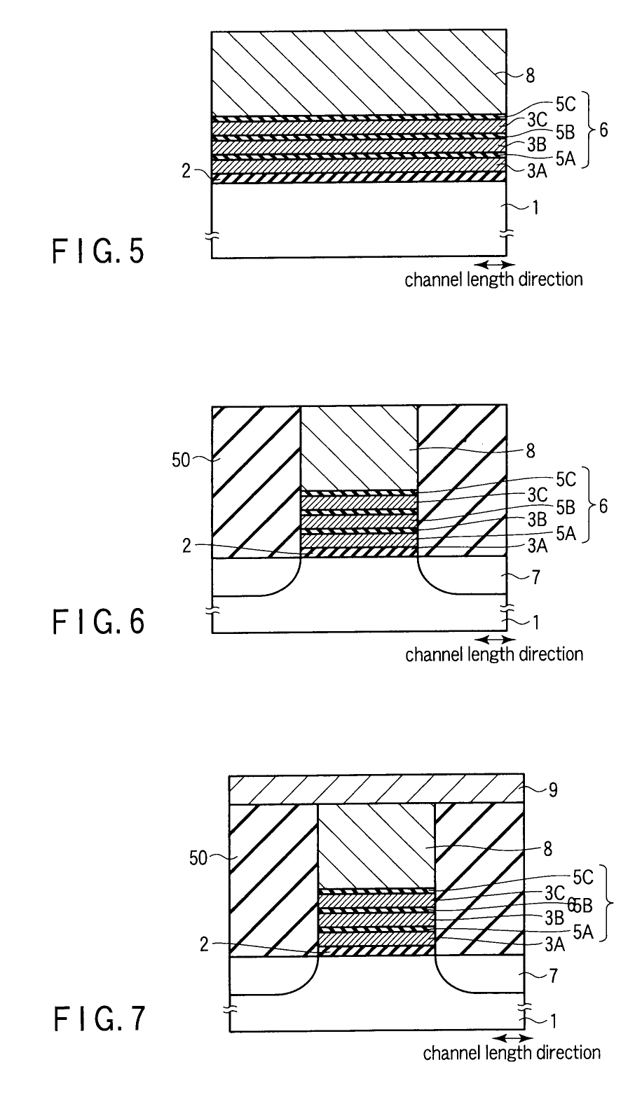

Further, as shown in FIG. 5, a silicon layer 8 (e.g., polysilicon layer) is formed on the stack 6 by, for example, the CVD method.

Then, as shown in FIG. 6, the silicon layer 8 is patterned by, for example, a photolithographic technique so that this silicon layer 8 may have a predetermined gate pattern before the silicon layer 8 and the stack 6 are subjected to gate fabrication by, for example, a reactive ion etching (RIE) method. The silicon layer 8 having been subjected to the gate fabrication is used as a mask to form source/drain diffusion layers 7 in the semiconductor substrate 1 by, for example, an ion implantation method. Then, an ion impurity contained in the source/drain diffusion layers 7 is activated by annealing, and immobilized in the semiconductor substrate 1.

Subsequently, an interlayer insulating film 50 is formed by, for example, the CVD method over the silicon layer 8 and the stack 6 which have been subjected to the gate fabrication. The interlayer insulating film 50 is planarized by, for example, a chemical mechanical polishing (CMP) method so that its upper surface may be substantially coincident with the upper surface of the silicon layer 8. Thus, the upper surface of the silicon layer 8 is exposed.

Then, as shown in FIG. 7, a metal film 9 of, for example, nickel (Ni) is formed over the entire surface of the semiconductor substrate by, for example, a sputtering method. As a result, the metal film 9 is formed on the upper surface of the silicon layer 8. In addition, the metal film 9 is not limited to Ni, and may be made of cobalt (Co), titanium (Ti), tungsten (W) or molybdenum (Mo).

Then, the silicon layer 8 and the metal film 9 are heated to carry out silicidation (silicidation processing) based on a solid-phase reaction. Thus, as shown in FIG. 1, a silicide layer 4B is formed on the stack 6. In addition, the metal film which has not caused a solid-phase reaction with the silicon layer 8 is removed after the silicidation processing.

During this silicidation processing, Ni atoms move in the silicon layer 8 while causing the solid-phase reaction (silicide reaction) with silicon (Si) atoms. The Ni atoms having reached the interface between the silicide layer 4B and the stack 6 diffuse into the stack 6.

The insulating films 5A, 5B, 5C included in the stack 6 function as stoppers for preventing the diffusion of the Ni atoms. However, the thickness of each of the insulating films 5A, 5B, 5C is extremely small (1 nm to 2 nm), so that a single insulating film (e.g., the insulating film 5C) alone cannot prevent the diffusion of all the Ni atoms. Therefore, of the conductive films included in the stack 6, the conductive film 4A formed on the side of the silicide layer 4B reacts with the Ni atoms which have passed through the insulating film 5C during the silicidation processing, and becomes a silicide film 4A.

Thus, as the thickness of each of the insulating films 5A, 5B, 5C is extremely small, some of the Ni atoms pass through the insulating films, and cause the silicide reaction with the conductive film (polysilicon film). However, along with the diffusion of the Ni atoms from the side of the silicide layer 4B to the side of the gate insulating film 2, the Ni atoms are gradually trapped by the plurality of insulating films 5A, 5B, 5C. At the same time, the Ni atoms which have passed through the insulating films 5A, 5B, 5C sequentially react with the conductive film (polysilicon film). Thus, the number of Ni atoms moving in the stack 6 toward the gate insulating film 2 decreases. Therefore, there are few Ni atoms that come into the conductive film 3A formed on the side of the gate insulating film 2, and the conductive film 3A does not entirely become a silicide film.

Hence, of the conductive films included in the stack 6, the conductive film 3A formed on the side of the gate insulating film 2 remains as it was at the time of the formation of the stack 6, that is, remains as the polysilicon film 3A.

Furthermore, along with the diffusion of the Ni atoms from the side of the silicide layer 4B to the side of the gate insulating film 2, the number of diffusing Ni atoms gradually decreases as described above. Therefore, the composition ratio of Ni to Si differs in each of the plurality of conductive films 3A, 3B, 4A in the stack 6.

That is, the composition ratio of the Ni atoms to the Si atoms in the conductive film on the side of the silicide layer 4B of the plurality of conductive films is higher than the composition ratio of the Ni atoms to the Si atoms in the conductive film on the side of the gate insulating film 2. Thus, the composition ratio of the Ni atoms to the Si atoms in the conductive film 3B between the conductive film 4A (silicide film) and the conductive film 3A (polysilicon film) is lower than the composition ratio of the Ni atoms in the conductive film 4A and higher than the composition ratio of the Ni atoms in the conductive film 3A.

In addition, although three conductive films and three insulating films constituting the stack 6 are formed in FIGS. 4 to 7, the number of stacked layers is not limited. That is, in the present embodiment, the number of conductive films and insulating films to be stacked has only to be such that the Ni atoms (metal atoms) may not diffuse in the conductive film (polysilicon film) 3A immediately on the gate insulating film 2. Moreover, the conductive film 3A on the gate insulating film 2 has only to be prevented from being entirely transformed into a silicide film. That is, part of the conductive film 3A in direct contact with the gate insulating film 2 has only to be prevented from being transformed into a silicide film, and the part which is in direct contact with the insulating film 5A may be a silicide film.

Thus, even after the silicide processing for forming a gate electrode, the polysilicon film 3A remains on the immediate gate insulating film 2. Therefore, the difference of work function between the semiconductor substrate (silicon substrate) 1 and the gate electrode 10 is determined in the silicon substrate 1 and the polysilicon film 3A, and there is almost no variation in the threshold voltage of the MIS transistor due to nonuniformity of the silicide film. Consequently, it is possible to prevent any element-by-element variation in the threshold voltage in the MIS transistor due to nonuniformity of the silicide layer immediately on the gate insulating film 2.

The MIS transistor in the embodiment of the present invention is formed by the manufacturing process described above.

As described above, in the present embodiment, the gate electrode 10 of the MIS transistor is composed of the stack 6 in which a plurality of conductive films and a plurality of insulating films are alternately stacked, and the silicide layer 4B. The plurality of insulating films 5A, 5B, 5C included in the stack 6 prevent the Ni atoms (metal atoms) which diffuse in the gate electrode during the formation of the silicide layer 4B from diffusing in the stack 6. As a result, the diffusion of the Ni atoms is stopped in any of the insulating films or conductive films in the stack 6, and the gate electrode 10 is not entirely silicided.

Accordingly, there is almost no variation in the threshold voltage of the MIS transistor due to the nonuniformity of the silicide layer on the immediate gate insulating film 2.

Furthermore, the plurality of insulating films 5A, 5B, 5C are included in the stack 6 in the MIS transistor formed by the above-described manufacturing method, and these insulating films are extremely small in thickness. Therefore, when the formed MIS transistor is driven, a drive voltage applied to the gate electrode 10 is provided between the silicide layer 4B and the polysilicon film 3A formed on the gate insulating film 2 with a small potential drop. Thus, a channel (inversion layer) is formed in the semiconductor substrate 1 under the gate insulating film 2, so that the operation of the MIS transistor is not disturbed by the stack 6 including the plurality of insulating films.

Consequently, according to the manufacturing method of the MIS transistor in the first embodiment of the present invention, it is possible to provide a MIS transistor and a semiconductor integrated circuit with the MIS transistor that operate stably.

### [2] Second Embodiment

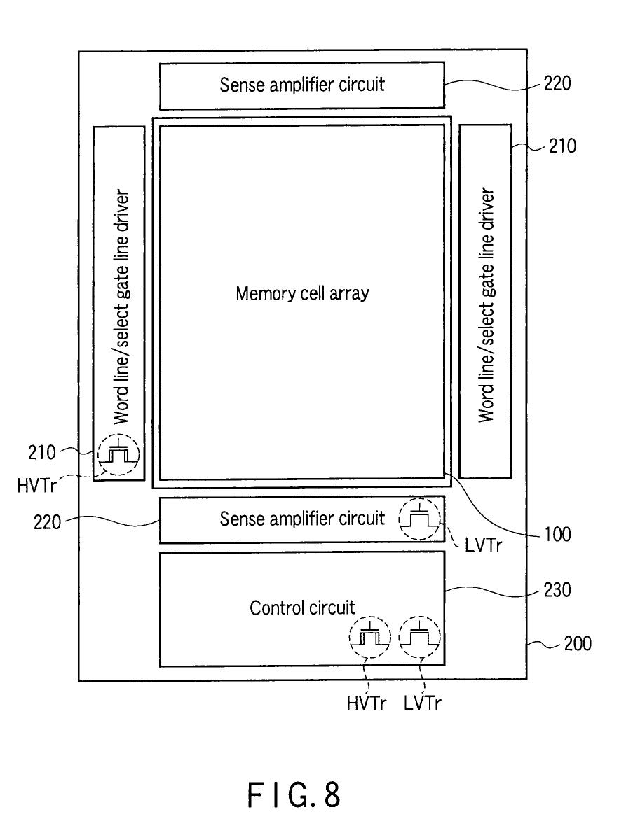

A second embodiment of the present invention is described below with FIGS. 8 to 20.

The structure and manufacturing method of one MIS transistor have been described in the first embodiment of the present invention. The MIS transistor described in the first embodiment is used as, for example, a logic circuit or a component of a memory circuit.

In the example described in the second embodiment of the present invention, the above-described MIS transistor is used as a component of a nonvolatile semiconductor memory such as a flash memory.

FIG. 8 is a schematic diagram showing the overall configuration of the flash memory.

As shown in FIG. 8, the flash memory mainly comprises a memory cell array region 100 and a peripheral circuit region 200 therearound. These regions are provided on the same chip (semiconductor substrate).

A plurality of memory cells and a plurality of select transistors are provided in the memory cell array region 100. The memory cells function as storage elements, and the select transistors function as switch elements for the memory cell selected for data writing/reading.

A word line/select gate line driver 210, a sense amplifier circuit 220 and a control circuit 230 are provided in the peripheral circuit region 200. These circuits 210, 220, 230 are composed of a plurality of MIS transistors (hereinafter also referred to as peripheral transistors). The peripheral transistors are classified into low-breakdown-voltage MIS transistors and high-breakdown-voltage MIS transistors in accordance with the functions of their circuits and elements. The MIS transistors described in FIGS. 1 to 3 are used as low-breakdown-voltage MIS transistors and high-breakdown-voltage MIS transistors.

(1) Structure

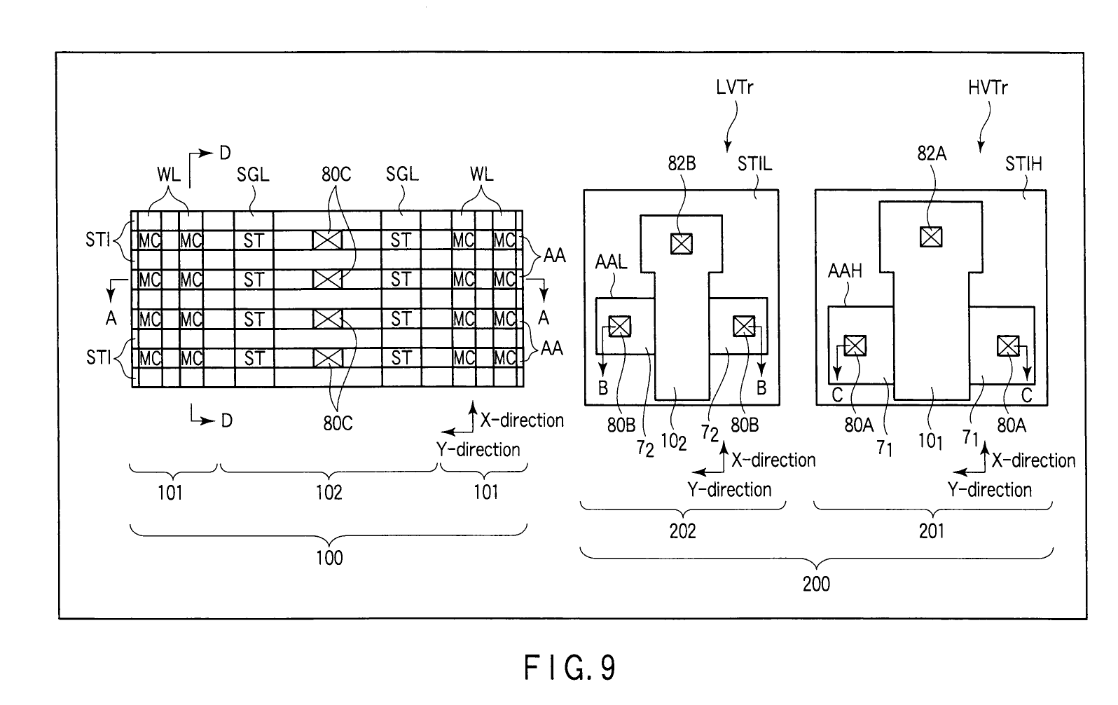

The structure of the flash memory according to the embodiment of the present invention is described with FIGS. 9 to 13.

FIG. 9 shows the planar structure of the flash memory according to the second embodiment of the present invention.

As shown in FIG. 9, the surface region of the memory cell array region 100 comprises a plurality of active regions AA and a plurality of isolation regions STI. The active regions AA and the isolation regions STI extend in a Y-direction, and one active region AA intervenes between two isolation regions STI.

A plurality of word lines WL extend in an X-direction, and intersect with the active regions AA. A plurality of memory cells MC are provided at the intersections of the word lines WL and the active regions AA. Select gate lines SGL extend in the X-direction similarly to the word lines WL, and select transistors ST are provided at the intersections of the select gate lines SGL and the active regions AA.

In the active regions AA, source/drain diffusion layers (not shown) of the memory cells MC and the select transistors ST are provided. The source/drain diffusion layers are shared by the memory cell MC and the select transistor ST adjacent to each other in the Y-direction, so that the plurality of memory cells MC and the select transistor ST are connected in series in the Y-direction. Moreover, a contact 80C is provided on the source/drain diffusion layer of two select transistors ST adjacent to each other in the Y-direction, and one contact 80C is shared by two select transistors ST.

Hereinafter, in the present embodiment, in the memory cell array region 100, a region where the memory cells are arranged (formed) is referred to as a memory cell formation region 101, while a region where the select transistors are arranged (formed) is referred to as a select gate formation region 102.

A plurality of high-breakdown-voltage MIS transistors HVTr and a plurality of low-breakdown-voltage MIS transistor LVTr are provided as the peripheral transistors in the peripheral circuit region 200. In the present embodiment, one high-breakdown-voltage MIS transistor and one low-breakdown-voltage MIS transistor are shown for the simplification of explanation. Hereinafter, in the present embodiment, outside of the peripheral circuit region 200, a region where the high-breakdown-voltage MIS transistor is disposed (formed) is referred to as a high-breakdown-voltage region 201, while a region where the low-breakdown-voltage MIS transistor is disposed (formed) is referred to as a low-breakdown-voltage region 202.

The high-breakdown-voltage and low-breakdown-voltage region 201, 202 are each enclosed by the isolation region STIH and STIL, and are provided with active regions AAH, AAL electrically separated from each other, respectively.

Gate electrodes 101, 102 of the peripheral transistors HVTr, LVTr extend in the X-direction across the active regions AAH, AAL, and are drawn up to isolation regions STIH, STIL. Contacts 82A, 82B are provided on the gate electrodes 10₁, 10₂ in their drawn portions. Further, source/drain diffusion layers 7₁ 7₂ are provided in the active regions AAH, AAL. Moreover, contacts 80A, 80B are connected onto the source/drain diffusion layers 7₁, 7₂.

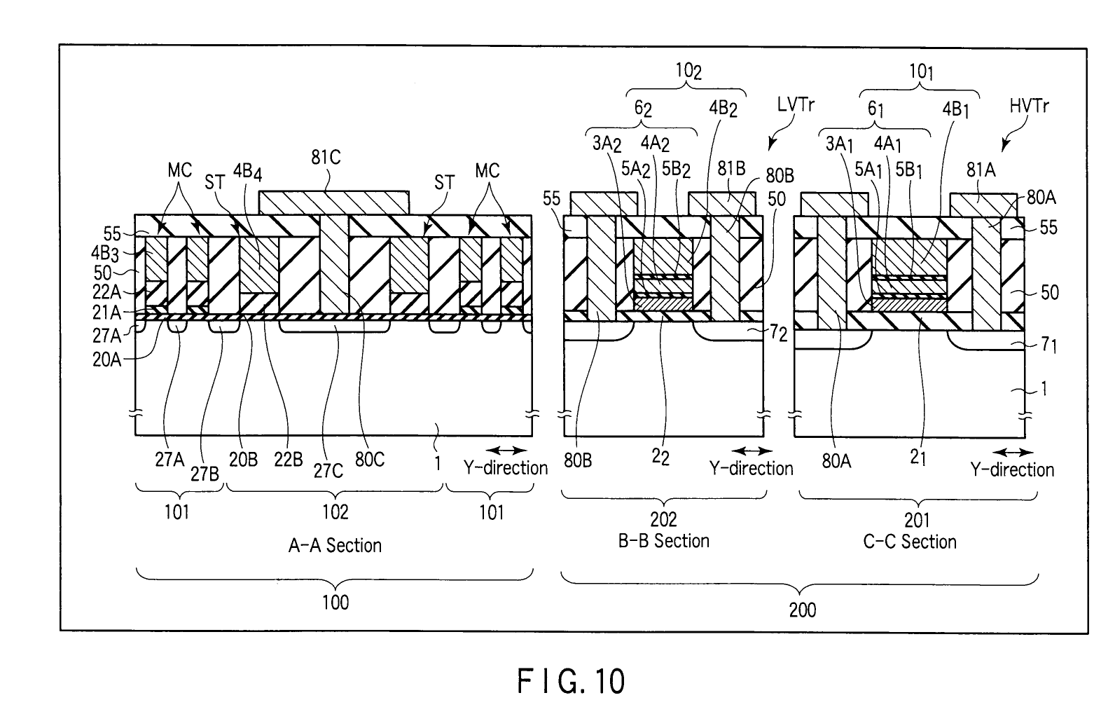

FIG. 10 shows sectional structures along the line A-A, the line B-B and the line C-C in FIG. 9.

As shown in FIG. 10, the memory cells MC provided in the memory cell formation region 101 are field efect transistors having a metal-oxide-nitride-oxide-semiconductor (MONOS) structure.

In the gate structure of the memory cell MC, a storage layer 21A is provided on a gate insulating film 20A on the surface of a semiconductor substrate 1, and an intermediate insulating film 22A is provided between the storage layer 21A and a gate electrode 4B₃. Further, the memory cell MC has a source/drain diffusion layer 27A, and this source/drain diffusion layer 27A is shared by the memory cells MC adjacent in the Y-direction (channel length direction).

The gate insulating film (first gate insulating film) 20A is, for example, a silicon oxide film having a thickness of about 4 nm, and functions as a tunnel insulating film during the injection of a charge into the storage layer 21A. For the gate insulating film 20A, use is made of an ONO film having a stack structure composed of a silicon oxide film, a silicon nitride film and a silicon oxide film, or a film in which layers of, for example, germanium (Ge) including an injection assist level are located at both interfaces of a tunnel film in the gate insulating film 20A. This makes it possible to improve the reliability of the gate insulating film and further improve write/erase characteristics. Hereinafter, the gate insulating film 20A is referred to as a tunnel insulating film 20A.

When the memory cells MC are the transistors of a MONOS structure, a film having a charge trapping function, that is, containing a large number of charge trapping levels is used for the storage layer 21A, and this film is an insulating film such as a silicon nitride film. When the storage layer 21A is a silicon nitride film, its thickness is about 3 nm to 10 nm. The storage layer 21A stores data such that the amount (number) of electrons stored therein corresponds to data of two or more values.

When a voltage is applied to the gate electrodes 4B₃, the intermediate insulating film 22A blocks a charge trapped in the storage layer 21A from being released to the gate electrodes 4B₃. Hereinafter, the intermediate insulating film 22A having such a function is referred to as a block insulating film 22A. The block insulating film 22A is a high dielectric film of, for example, Al₂O₃, HfO₂, Ta₂O₅, La₂O₃, LaLiO₃, ZrO₂, Y₂O₃ or ZrSiO₄. Alternatively, the block insulating film 22A may be a composite film of these materials, or a stack film of these films and a SiN film or SiO₂ film. When the block insulating film 22A is an alumina film, its thickness is, for example, about 10 nm to 30 nm.

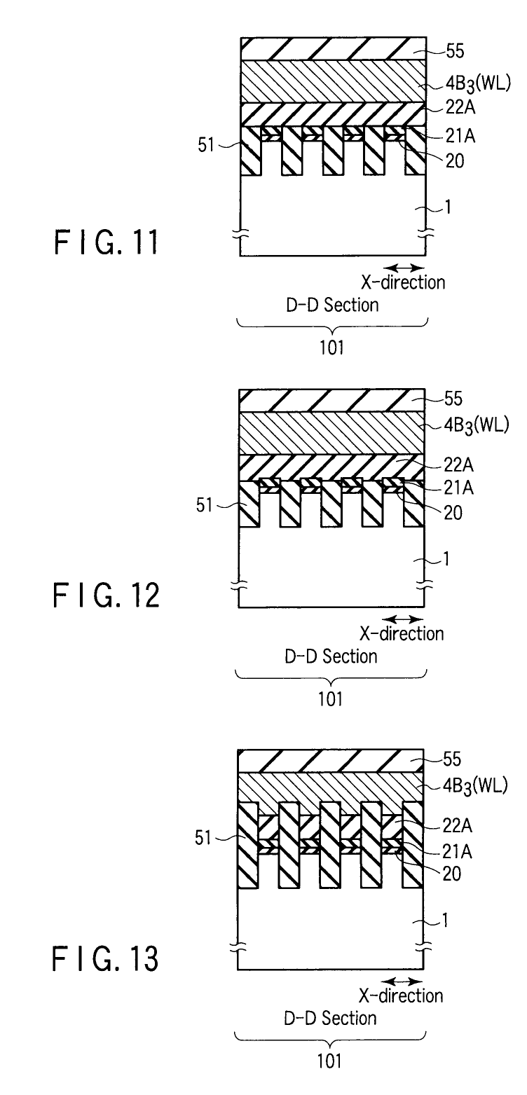

Furthermore, FIG. 11, FIG. 12 and FIG. 13 show examples of sectional structures along the line D-D in FIG. 7. The memory cell MC has one of the sectional structures in the X-direction (channel width direction) in FIGS. 11 to 13.

The storage layer 21A is electrically separated by an isolation insulating film 51 embedded in an isolation region STI in the X-direction (channel width direction), for example, as shown in FIG. 11, FIG. 12 and FIG. 13. In addition, the sectional structure of the storage layer 21A in the X-direction is not limited to the examples shown in FIGS. 11 to 13. For example, if the storage layer 21A is an insulating film, this film does not have to be separated by the memory cells MC adjacent in the X-direction, and the storage layer 21A may be structured to extend in the X-direction over the active region AA and over the isolation region STI.

The block insulating film 22A may extend in the X-direction over the storage layer 21A and over the isolation insulating film 51, as shown in FIG. 11. When the isolation insulating film 51 is structured so that its upper surface is dropped to a position lower than the upper surface of the storage layer 21A and higher than the lower surface of the storage layer 21A as shown in FIG. 12, the block insulating film 22A may be structured to cover the side surfaces of the storage layer 21A in the X-direction. Alternatively, as shown in FIG. 13, the block insulating film 22A may be separated by the isolation insulating film 51 for the memory cells MC adjacent in the X-direction.

The gate electrode (first gate electrode) 4B₃ extends in the X-direction as shown in FIG. 11, FIG. 12 or FIG. 13, is shared by the plurality of memory cells MC memory cells MC adjacent in the X-direction, and functions as the word line WL. The gate electrode 4B₃ is configured by a single silicide layer (first silicide layer), and has a FUSI structure. The gate electrode 4B₃ is formed not exclusively but of, for example, a NiSi₂ layer, and may be formed of any other silicide material.

The select transistor ST provided in the select gate formation region 102 shown in FIG. 10 has, for example, the following configuration. The gate structure of the select transistor ST comprises a gate insulating film 20B on the surface of the semiconductor substrate 1, an intermediate insulating film 22B on the gate insulating film 20B, and a gate electrode 4B₄ on the intermediate insulating film 22B. Further, the select transistor ST has source/drain diffusion layers 27B, 27C provided in the semiconductor substrate 1. The source/drain diffusion layer 27B is shared with the memory cell MC adjacent in the Y-direction, such that the select transistor ST is connected in series to the memory cell MC. The source/drain diffusion layer 27C is connected to the contact 80C embedded in an interlayer insulating film 50, and connected to a interconnect layer 81C via the contact 80C.

The thickness of the insulating film 20B provided on the semiconductor substrate 1 in the select gate formation region 102 is greater than the thickness of the tunnel insulating film 20A of the memory cell MC, and is, for example, about 7 nm. The intermediate insulating film 22B is provided on the gate insulating film 20B. The intermediate insulating film 22B is formed simultaneously with the block insulating film 22A of the memory cell MC. Therefore, the intermediate insulating film 22B has the same configuration as the block insulating film 22A, and is, for example, an alumina film of about 10 nm to 30 nm.

In the present embodiment, the gate insulating film 20B and the intermediate insulating film 22B function as the gate insulating films of the select transistor ST. It has been heretofore the case that the gate length of the select transistor ST is greater than the gate length of the memory cell MC in order to ensure a drain-source breakdown voltage and a gate breakdown-voltage. However, in the present embodiment, the gate insulating film can be sufficiently increased in thickness, so that sufficient drain-source breakdown voltage and gate breakdown-voltage are ensured, and the gate length of the select transistor ST can be small.

The gate electrode 4B₄ of the select transistor ST extends in the X-direction. The gate electrode 4B₄ is shared by the plurality of select transistors ST adjacent in the X-direction, and functions as the select gate line SGL. The gate electrode 4B₄ as the select gate line SGL is formed simultaneously with the gate electrode 4B₃, and therefore has the same configuration as the word line WL.

Furthermore, in the present embodiment, the select transistor ST is not provided with the storage layer 21A made of an insulating film, and only has the intermediate insulating film 22B of the same configuration as the block insulating film 22A interposed between the gate insulating film 20B and the gate electrode 4B₄. Therefore, in the select transistor ST of the present embodiment, charge is not injected into the storage layer 21A even if a voltage is applied to the gate electrode 4B₄, and there is no variation in the threshold voltage of the select transistor ST due to the charge trapping of the storage layer. However, as far as the variation characteristics of threshold voltage of the select transistor ST are permitted in designing, a film of the same configuration as the storage layer may be present between the gate insulating film 20B and the block insulating film 22A.

The high-breakdown-voltage/low-breakdown-voltage MIS transistors HVTr, LVTr shown in FIG. 10 have similar structures. The high-breakdown-voltage/low-breakdown-voltage MIS transistor HVTr, LVTr has the two source/drain diffusion layers 7₁, 7₂ in the semiconductor substrate 1, a gate insulating film 2₁, 2₂ provided on the surface of the semiconductor substrate 1 between the two source/drain diffusion layers 7₁, 7₂, and the gate electrodes 10₁, 10₂ on a gate insulating film 21. The source/drain diffusion layers 7₁, 7₂ are connected to interconnect layers 81A, 81B via the contacts 80A, 80B in the interlayer insulating film 50.

The high-breakdown-voltage MIS transistor HVTr provided in the high-breakdown-voltage region 201 is responsible for the transfer of a high voltage such as a program voltage. Thus, the thickness of its gate insulating film 2₁ is greater than the thickness of a gate insulating film 2₂ of the low-breakdown-voltage MIS transistor LVTr, such that the gate breakdown voltage of the high-breakdown-voltage MIS transistor HVTr is ensured. For example, the thickness of the gate insulating film 2₁ is about 30 nm or more and 50 nm or less.

The low-breakdown-voltage MIS transistor LVTr provided in the low-breakdown-voltage region 202 functions as, for example, a switch element of a logic circuit. The thickness of the gate insulating film 2₂ of the low-breakdown-voltage MIS transistor LVTr is, for example, about 6 nm to 9 nm. Moreover, the gate length of the high-breakdown-voltage/low-breakdown-voltage MIS transistors HVTr, LVTr is greater than the gate length of the select transistor ST and the memory cell MC in order to ensure a drain-source breakdown voltage.

The gate electrodes 10₁, 10₂ of the high-breakdown-voltage/low-breakdown-voltage MIS transistors HVTr, LVTr are composed of stacks 6₁, 6₂ on the gate insulating films 2₁, 2₂, and silicide layers 4B₁, 4B₂ on the stacks 6₁, 6₂, respectively. In addition, although the stack 6₁ is composed of two insulating films 5A₁, 5A₂ and two conductive films 3A₁, 4A₁ in FIG. 10, the number of stacked layers is not limited. This holds true with the stack 6₂. Moreover, it is preferable, from the viewpoint of simplification of the manufacturing process that the number of stacked layers in the stack 6₁ be the same as the number of stacked layers in the stack 6₂.

Of the plurality of conductive films included in the stacks 6₁, 6₂, the conductive films 3A₁, 3A₂ in direct contact with the gate insulating films 2₁, 2₂ are, for example, polysilicon films. Moreover, of the plurality of conductive films included in the stacks 6₁, 6₂, the conductive films 4A₁, 4A₂ on the side of the silicide layers 4B₁, 4B₂ are, for example, silicide films.

The plurality of conductive films constituting the stacks 6₁, 6₂ contain metal atoms attributed to the silicide layers 4B₁, 4B₂. There is a difference in the number of metal atoms contained in the plurality of conductive films between the side of the gate electrodes (silicide layers 4B₁, 4B₂) and the side of the gate insulating films. Specifically, the number of metal atoms in the conductive films on the side of the silicide layer 4B₁, 4B₂ is greater than the number of metal atoms in the conductive films on the side of the gate insulating films. The number of metal atoms contained in the plurality of conductive films gradually decreases from the side of the gate electrodes to the side of the gate insulating films.

The insulating films 5A₁, 5B₁, 5A₂, 5B₂ in the stacks 6₁, 6₂ inhibit the metal atoms (Ni atoms) from diffusing into the entire the stacks 6₁, 6₂ during the silicidation of the gate electrodes. The thickness of the insulating films 5A₁, 5B₁, 5A₂, 5B₂ is smaller than the thickness of the tunnel insulating film 20A, and is, for example, about 1 nm to 2 nm.

Thus, as in the MIS transistor described in the first embodiment, the peripheral transistors HVTr, LVTr provided in the peripheral circuit region 200 have the stacks 6₁, 6₂ in which the plurality of conductive films and the plurality of insulating films are alternately stacked, between the silicide layers (second silicide layers) 4B₁, 4B₂ and the gate insulating films 2₁, 2₂.

A common manufacturing process is used for the memory cell array region 100 and the peripheral circuit region 200 in the flash memory for A simplification of the manufacturing process. Therefore, the gate electrodes of the high-breakdown-voltage and low-breakdown-voltage MIS transistors HVTr, LVTr are also silicided during the silicidation of the gate electrode 4B₃ of the memory cell MC to reduce reducing the resistance of the word lines WL.

In the present embodiment, the gate electrode 4B₃ of the memory cell MC has a FUSI structure by the silicidation processing. However, in the MIS transistors such as the high-breakdown-voltage/low-breakdown-voltage MIS transistors HVTr, LVTr, the conductive films 3A₁, 3A₂ in direct contact with the gate insulating films 2₁, 2₂ of the plurality of conductive films included in the stacks 6₁, 6₂ are not silicided, and become polysilicon films. Therefore, the difference in work function between the gate electrodes 10₁, 10₂ and the semiconductor substrate 1 is determined by the polysilicon films included in the gate electrodes 10₁, 10₂ and by the silicon substrate used as the substrate 1. Further, the threshold voltages of the peripheral transistors HVTr, LVTr are defined by the difference of work function between in polysilicon films and the silicon substrate.

As a result, as in the first embodiment, it is possible to inhibit any element-by-element variation in the threshold voltage in the peripheral transistors (MIS transistors) HVTr, LVTr due to nonuniformity of the silicide layers included in the gate electrodes 10₁, 10₂.

In addition, as in the first embodiment, the insulating films included in the stacks 6₁, 6₂ are extremely thin. Therefore, a drive voltage applied to the gate electrodes 10₁, 10₂ is provided between the silicide layers 4B₁, 4B₂ and the polysilicon films 3A₁, 3A₂ formed on the gate insulating films with a small potential drop. Thus, a channel (inversion layer) is formed in the semiconductor substrate 1 immediately under the gate insulating films 2₁, 2₂, so that the peripheral transistors HVTr, LVTr can be normally driven even if the stacks 6 including the plurality of insulating films are provided on the gate insulating films 2₁, 2₂.

Consequently, according to the second embodiment of the present invention, it is possible to stabilize the operation of the flash memory.

(2) Manufacturing Method

(2-1) Manufacturing Method 1

A manufacturing method of the flash memory according to the second embodiment of the present invention is described with FIGS. 10, 14 to 19. It should be noted that manufacturing steps are explained using the sectional structures of a memory cell array region 100 and a peripheral circuit region 200 in the Y-direction and that a manufacturing step of a section in the X-direction is explained when necessary.

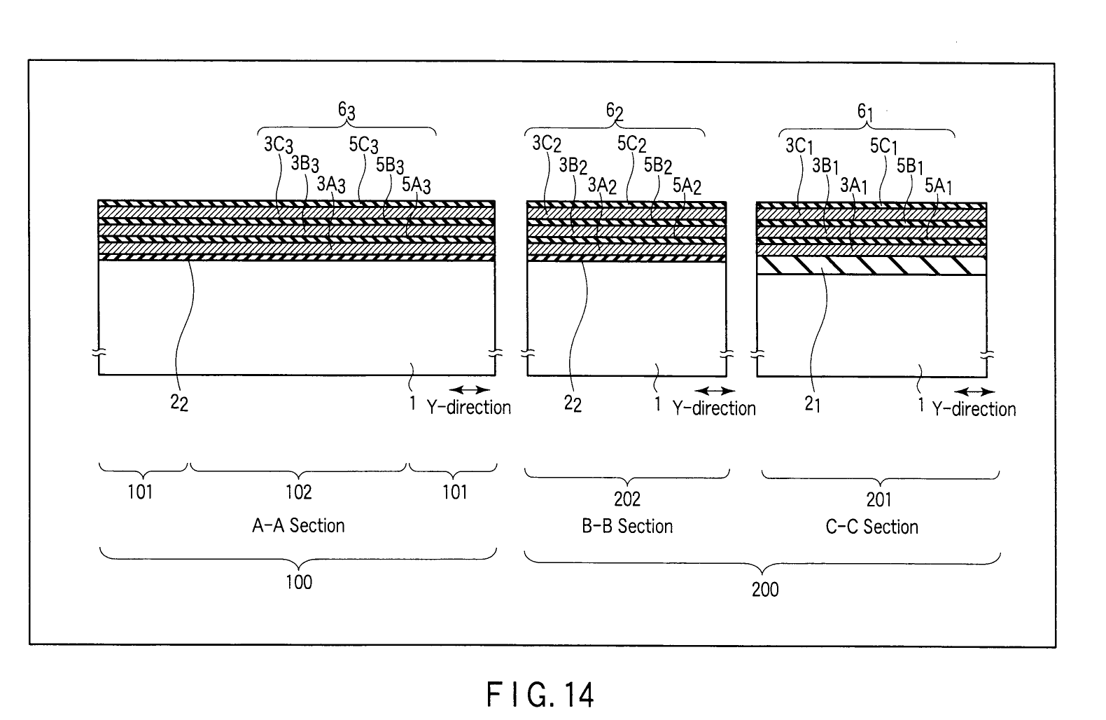

As shown in FIG. 14, in the peripheral circuit region 200, a semiconductor substrate 1 is etched by, for example, the reactive ion etching (RIE) method in a high-breakdown-voltage region 201, so that a recess is formed in the semiconductor substrate 1. That is, the surface of the semiconductor substrate 1 in the high-breakdown-voltage region 201 is lower than the surface of the semiconductor substrate 1 in the memory cell array region 100 and a low-breakdown-voltage region 202.

Furthermore, a sacrificial oxide film (not shown) is formed on the surface of the semiconductor substrate 1. Then, for example, different dose amounts of ions are implanted into high-breakdown-voltage/low-breakdown-voltage regions 201, 202 in the memory cell array region 100 and the peripheral circuit region 200, and a well region (not shown) with impurity concentration corresponding to each element formation region is formed.

After the sacrificial oxide film is released, the semiconductor substrate 1 is, for example, thermally oxidized, and an insulating film (e.g., silicon oxide film) of about 30 nm to 50 nm is formed on the surface of the semiconductor substrate 1. This silicon oxide film is removed in the memory cell array region 100 and the low-breakdown-voltage region 202 by, for example, the photolithographic technique and the RIE method, and is left unremoved in the recess (the surface of the semiconductor substrate 1) in the high-breakdown-voltage region 201. A silicon oxide film 21 remaining in the high-breakdown-voltage region 201 serves as a gate insulating film of a high-breakdown-voltage MIS transistor.

Then, the surface of the semiconductor substrate 1 is, for example, thermally oxidized again, and a silicon oxide film 2₂ is formed on the surface of the semiconductor substrate 1 in the memory cell array region 100 and the low-breakdown-voltage region 202. The silicon oxide film 2₂ serves as a gate insulating film of a low-breakdown-voltage MIS transistor, and its thickness is about 6 nm. In addition, in order to reduce the step between regions, a recess is preferably formed in the high-breakdown-voltage region 201 so that the upper end of the silicon oxide film 2₁ is substantially coincident with the upper end of the silicon oxide film 2₂.

Furthermore, a plurality of conductive films 3A₁ to 3A₃, 3B₁ to 3B₃, 3C₁ to 3C₃ and a plurality of insulating films 5A₁ to 5A₃, 5B₁ to 5B₃, 5C₁ to 5C₃ are alternately stacked on the silicon oxide films 2₁, 2₂ in the memory cell array region 100 and the peripheral circuit region 200, and stacks 6₁ to 6₃ are formed in both the regions. The conductive films 3A₁ to 3A₃, 3B₁ to 3B₃, 3C₁ to 3C₃ are polysilicon films, and are formed to have a thickness of about 10 nm to 15 nm by, for example, the CVD method. Moreover, the insulating films 5A₁ to 5A₃, 5B₁ to 5B₃, 5C₁ to 5C₃ are formed to have a thickness of about 1 nm to 2 nm by, for example, the thermal oxidation method. In addition, the insulating films 5A₁ to 5A₃, 5B₁ to 5B₃, 5C₁ to 5C₃ may otherwise be native oxide films formed on the polysilicon films.

Subsequently, for example, the memory cell array region 100 and the peripheral circuit region 200 are patterned by the photolithographic technique, and the stack 6₃ and the insulating film 2₂ formed in the memory cell array region 100 are removed by, for example, the RIE method.

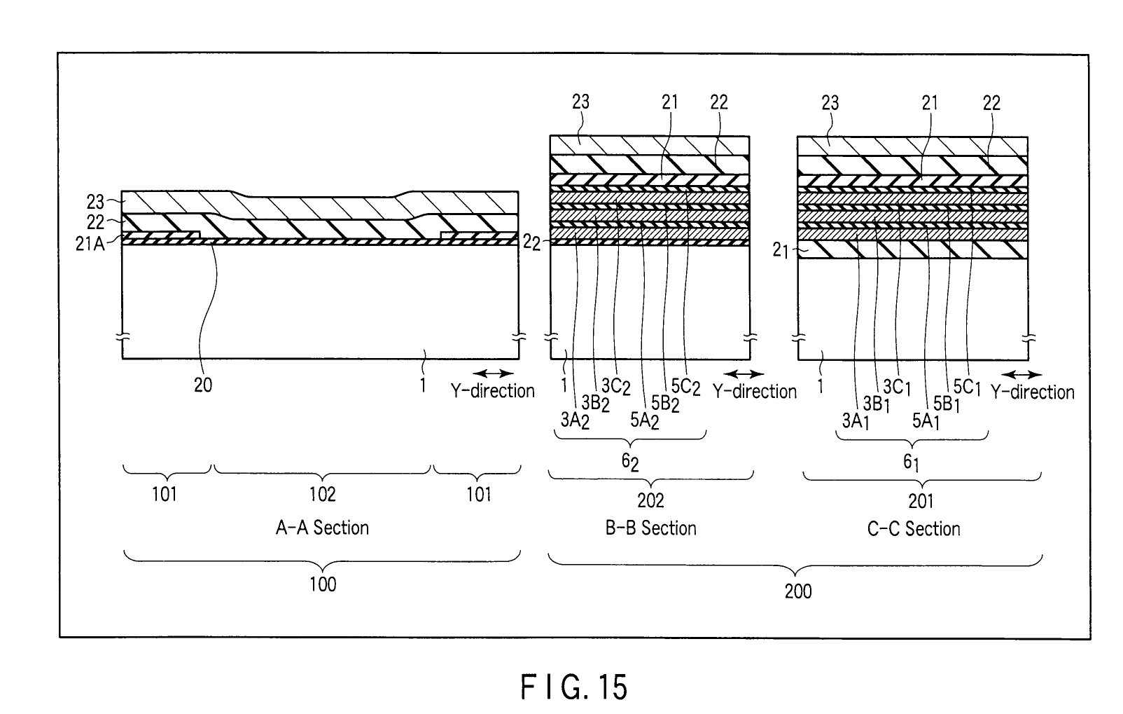

As shown in FIG. 15, a gate insulating film 20 is formed on the surface of the semiconductor substrate 1 in the memory cell array region 100 by, for example, a thermal oxidation method. The gate insulating film 20 is, for example, a silicon oxide film having a thickness of about 4 nm, and serves as a tunnel insulating film of a memory cell. For the gate insulating film 20, use may be made of an ONO film, or an insulating film in which layers of, for example, germanium (Ge) including an injection assist level are located at both interfaces of a tunnel film.

On the gate insulating film 20, a storage layer 21A is formed to have a thickness of about 4 nm to 6 nm by, for example, the CVD method. A silicon nitride film containing a large number of charge trapping levels, for example, is used for the storage layer 21A. Then, the storage layer 21A is etched by the photolithographic technique and the RIE method so that this storage layer may remain in a memory cell formation region 101 alone. The storage layer in a select gate formation region 10₂ is removed.

Here, when the sectional structure of the memory cell along the line D-D in FIG. 9 is as shown in FIG. 11, trenches are formed in the semiconductor substrate 1 by the photolithographic technique and the RIE method after the formation of the storage layer 21A. Isolation insulating film 51 is embedded into the trenches, so that active regions and isolation regions are formed. Active regions AA adjacent in the X-direction are electrically separated by the isolation insulating film 51.

In addition, trenches may be formed in the semiconductor substrate 1 by a hard mask instead of a resist mask. In this case, in order to ensure the etching selection ratio of the hard mask to the storage layer 21A, a first hard mask (not shown) different in material from the storage layer 21A is formed on the storage layer 21A, and a second hard mask different in material from the first hard mask is further formed on the first hard mask. The first hard mask is, for example, a silicon oxide film. The second hard mask is an amorphous silicon or silicon nitride film.

The isolation insulating film 51 is embedded into the formed trenches, and the isolation insulating film 51 is planarized by the CMP method using the hard mask as a stopper. Then, the isolation insulating film 51 is etched back so that the height of the upper surface of the isolation insulating film 51 may be coincident with the height of the upper surface of the storage layer 21A. Further, the hard masks remaining on the storage layer 21A are released. This also allows the active regions AA adjacent in the X-direction to be electrically separated by the isolation insulating film 51.

Furthermore, when the sectional structure of the memory cell along the line D-D indicated in FIG. 9 is as shown in FIG. 12, the isolation insulating film 51 is etched by, for example, the RIE method after the formation of the isolation insulating film 51 so that the upper surface of the isolation insulating film 51 in the memory cell formation region 101 may be lower than the upper surface of the storage layer 21A and higher than the lower surface of the storage layer 21A.

Then, an intermediate insulating film 22 and a first silicon layer (e.g., polysilicon layer) 23 are sequentially formed in the memory cell array region 100 by, for example, the CVD method.

In the memory cell formation region 101, the intermediate insulating film 22 is formed on the storage layer 21A. The intermediate insulating film 22 is, for example, an alumina (Al₂O₃) film about 10 nm to 30 nm thick. This intermediate insulating film 22 functions as a block insulating film of the memory cell. In addition, the intermediate insulating film 22 is not exclusively an alumina film, and may be any other high dielectric gate insulating film of, for example, HfO₂, or a single-layer insulating film such as a silicon nitride film or silicon oxide film, or a stack of insulating films such as an ONO film. On the other hand, in the select gate formation region 102, the storage layer is removed as described above, so that the intermediate insulating film 22 is in direct contact with the gate insulating film 20.

At the same time, in the peripheral circuit region 200, an insulating film 21 of the same configuration as the storage layer 21A, the intermediate insulating film 2and a first silicon layer 23 are formed on the stacks 6₁, 6₂.

In addition, when the storage layer in the select gate formation region 102 is removed, the insulating film 20 in this region 102 may be removed at the same time, and an insulating film thicker than the insulating film 20 may be newly formed. Moreover, the storage layer in the select gate formation region 102 is removed in the present embodiment, which is not however limitation. The storage layer may remain in the select gate formation region 102.

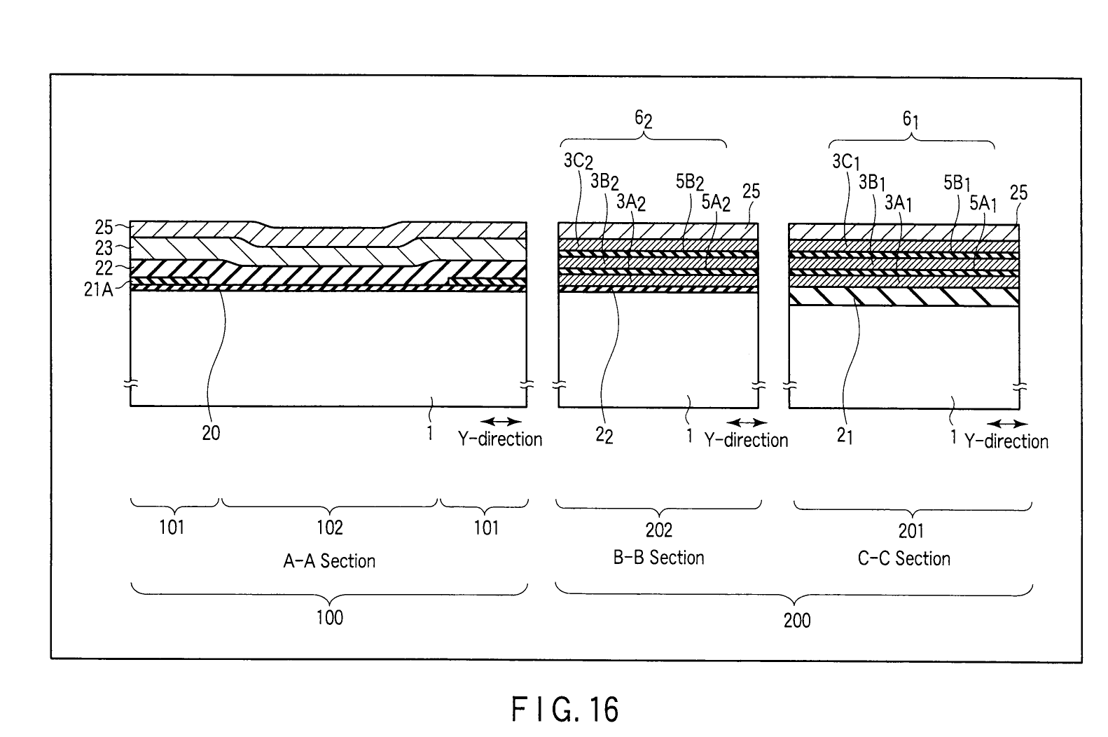

As shown in FIG. 16, the first silicon layer 23, the intermediate insulating film 22 and the insulating film 21 are removed on the stacks 6₁, 6₂ in the high-breakdown-voltage/low-breakdown-voltage regions 201, 202 by, for example, the photolithographic technique and the RIE method. At the same time, an oxide film (native oxide film) formed on the uppermost ends of the stacks 6₁, 6₂ is extremely thin and thus removed, and the conductive films (polysilicon films) 3C₁, 3C₂ provided immediately under this oxide film are also etched and reduced in thickness. The stacks 6₁, 6₂ are preferably formed so that the above-mentioned reduction in thickness is taken into account and so that the height of the upper ends of the stacks 6₁, 6₂ may be substantially coincident with the height of the upper end of the first silicon layer 23 in the memory cell formation region 101. This is intended to inhibit the difficulty of processing in the manufacturing process from increasing due to the step between the upper end of the memory cell array region 100 and the upper end of the peripheral circuit region 200.

Then, a second silicon layer 25 is formed on the first silicon layer 23 and the stacks 6₁, 6₂. In addition, no first silicon layer 23 may be formed. That is, after the formation of the intermediate insulating film 22, the intermediate insulating film 22 on the stacks 6₁, 6₂ alone may be removed, and then the second silicon layer 25 may be formed in the memory cell array region 100 and the peripheral circuit region 200. As a result, the step of forming the first silicon layer 23 can be omitted.

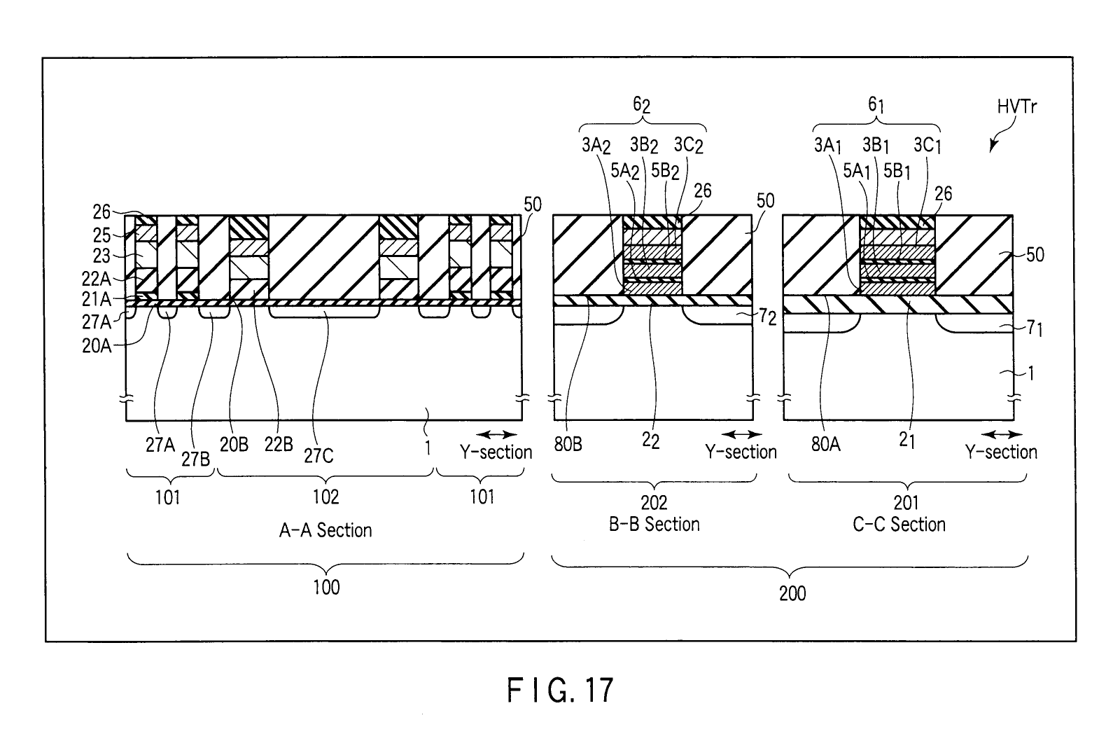

Then, as shown in FIG. 17, using a mask layer 26 made of, for example, a silicon nitride film as a hard mask, the conductive films and insulating films formed in the memory cell array region 100 and the peripheral circuit region 200 are subjected to gate fabrication by the photolithographic technique and the RIE method so that the memory cell MC, a select transistor ST and the high-breakdown-voltage/low-breakdown-voltage MIS transistors HVTr, LVTr may be formed into gate length for predetermined patterns.

Then, using, as masks, the first, second silicon layers 23, 25 and the stacks 6₁, 6₂ which have been subjected to the gate fabrication, source/drain diffusion layers 27A, 27B, 27C, 7₁, 7₂ are formed in the semiconductor substrate 1. Then, impurity ions contained in the source/drain diffusion layers 27A, 27B, 27C, 7₁, 7₂ are activated by annealing, and immobilized in the semiconductor substrate 1.

After the formation of the source/drain diffusion layers, an interlayer insulating film 50 is formed by, for example, the CVD method over the gates of the memory cell MC and the transistors St, HVTr, LVTr.

Then, the mask layer 26 is used as a stopper to carry out planarization by the CMP method. Here, a step is produced between the upper end of the memory cell formation region 101 and the upper end of the select gate formation region 102, and this step corresponds to the thickness of the storage layer 21A (about 4 nm to 6 nm). Therefore, the upper portion of the mask layer in the select gate formation region 102 is trimmed, so that the upper end of the memory cell formation region 101 becomes substantially equal in height to the upper end of the select gate formation region 102, and the upper end of the memory cell array region 100 becomes flat.

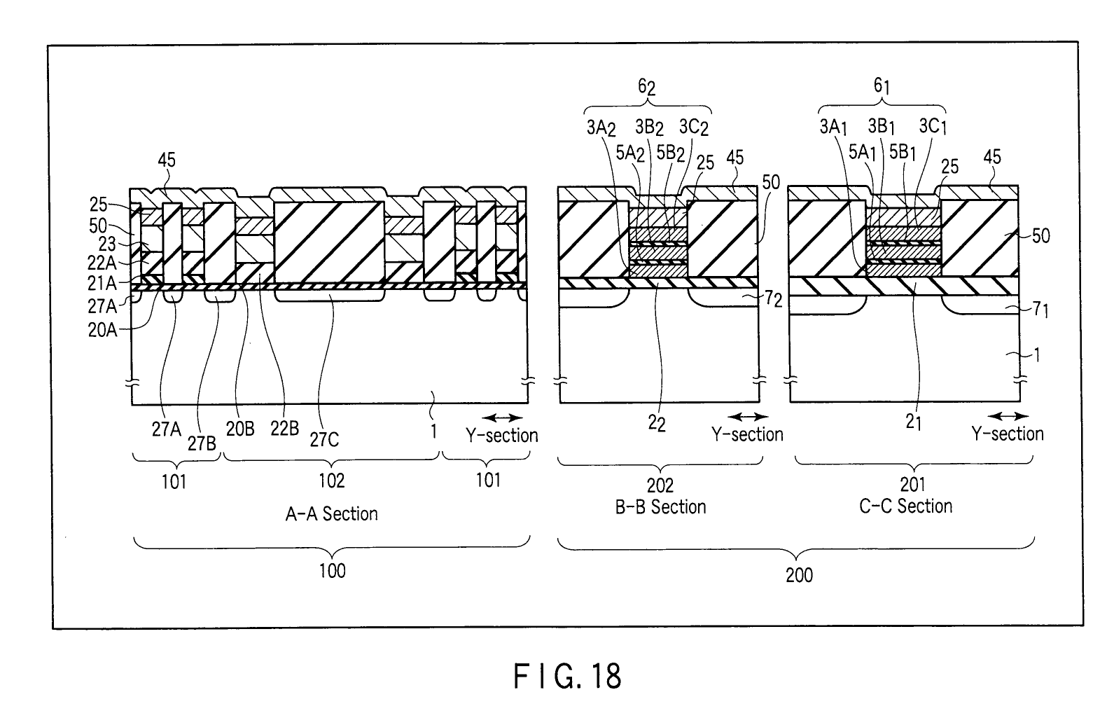

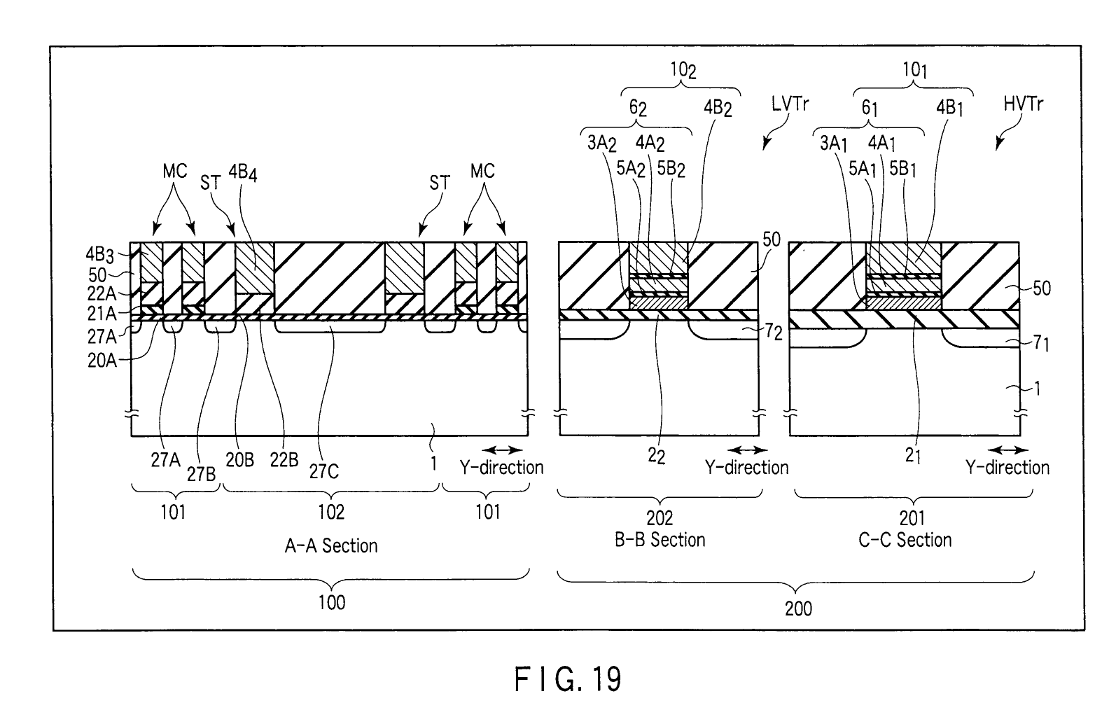

Then, the mask layer 26 is released, and the upper surface of the second silicon layer 25 is exposed as shown in FIG. 18. Further, a metal film such as a Ni film 45 is formed on the second silicon layer 25 by the sputtering method. At the same time, the Ni film 45 is formed on the second silicon layer 25 in the peripheral circuit region 200.

Then, silicidation processing by heating is carried out. As a result, Ni atoms contained in a Ni film 24 diffuse in the first, second silicon layers 23, 25 in the memory cell array region 100, while Ni atoms diffuse in the second silicon layer 25 and the stacks 6₁, 6₂ formed in the high-breakdown-voltage/low-breakdown-voltage regions 201, 202 in the peripheral circuit region 200. In addition, the metal film formed on the second silicon layer 25 is not exclusively a Ni film, and may be a film of other metal materials such as Co or Ti as long as silicide is formed between this material and polysilicon by heating. In addition, the metal film which has not caused a solid-phase reaction with the silicon layers and the conductive films is removed after the silicidation processing.

The whole polysilicon layer on the intermediate insulating film 2₂ is silicided by the above-mentioned heating as shown in FIG. 19, and a silicide (NiSi₂) layer 4B₃ is formed in the memory cell array region 100. Thus, the gate electrode of the memory cell can be a gate electrode of a FUSI structure owing to reduced resistance. Similarly, the gate electrode of the select transistor becomes a gate electrode 4B₄.

On the other hand, in the peripheral circuit region 200, the conductive film (polysilicon film) in direct contact with the Ni film in the stacks 6₁, 6₂ is silicided, and become silicide films 4B₁, 4B₂. Moreover, the insulating films 5A₁, 5A₂, 5B₁, 5B₂ have a small thickness of about 1 nm to 2 nm, so that the Ni atoms pass through the insulating films 5A₁, 5A₂, 5B₁, 5B₂ and then diffuse in the stacks 6₁, 6₂.

When the Ni atoms diffuse in the stacks 6₁, 6₂, the insulating films 5A₁, 5A₂, 5B₁, 5B₂ function as stoppers for the Ni atoms as in the first embodiment. Thus, as the Ni atoms move from the side of the silicide layer 4B₁, 4B₂ to the side of gate insulating films 2₁, 2₂, the number of diffusing Ni atoms gradually decreases. Each of the plurality of conductive films (polysilicon films) included in the stacks 6₁, 6₂ is silicided with a different composition ratio of the Ni atoms to the Si atoms, and not all of the plurality of conductive films included in the stacks 6₁, 6₂ become silicide films. Thus, the conductive films 3A₁, 3A₂ in direct contact with the gate insulating films 2₁, 2₂ can be polysilicon films. In addition, it is preferable to form the stacks 6₁, 6₂ in consideration of the number of stacked conductive films and insulating films so that the conductive films 3A₁, 3A₂ on the immediate gate insulating films 2₁, 2₂ are not be silicided.

Thus, in the memory cell formation region 10₁, the silicide layer (gate electrode) 4B₃, a block insulating film (intermediate insulating film) 22A and the storage layer 21A are formed on a tunnel insulating film 20A. Further, in the select gate formation region 102, the silicide layer (gate electrode) 4B₄ and an intermediate insulating film 22B of the same configuration as the block insulating film to be formed into predetermined gate sizes are formed on an insulating film 20B of the same configuration as the tunnel insulating film 20A. In the present embodiment, the intermediate insulating film 22B and the insulating film 20B function as gate insulating films in the select transistor ST.

In the high-breakdown-voltage/low-breakdown-voltage regions 201, 202, the silicide layers 4B₁, 4B₂ and the stacks 6₁, 6₂ are formed on the gate insulating films 2₁, 22. In addition, as described above, of the plurality of conductive films included in the stacks 6₁, 6₂, the conductive films 3A₁, 3A₂ in direct contact with the gate insulating films 2₁, 2₂ are polysilicon films.

Then, as shown in FIG. 10, an insulating layer 55 is formed on the insulating layer 50. Further, in the memory cell array region 100, a contact 80C is embedded in the insulating layers 50, 55 into contact with the source/drain diffusion layer 27C. Then, a interconnect layer 81C is formed on the insulating layers 50, 55 so that this interconnect layer 81C is electrically connected to the contact 80C. At the same time, in the high-breakdown-voltage region 201 and the low-breakdown-voltage region 202 within the peripheral circuit 200, contacts 80A, 80B are embedded in the insulating layer 50 into direct contact with the source/drain diffusion layers 7₁, 7₂. Moreover, interconnect layers 81A, 81B are formed on the insulating layers 50, 55 so that these interconnect layers 81A, 81B are electrically connected to the contacts 80A, 80B.

The flash memory according to the second embodiment of the present invention is completed by the manufacturing process described above.

In the second embodiment of the present invention, the stacks 6₁, 6₂ in which a plurality of conductive films and a plurality of insulating films are alternately stacked are formed on the gate insulating films 2₁, 2₂ in the region 200 where the MIS transistor (peripheral transistor) is provided. The silicon layers and the metal films (Ni films) on the stacks 6₁, 6₂ are silicided.

When a silicide layer is formed by a solid-phase reaction between the silicon layer and the Ni film, Ni atoms diffuse in the silicide layer and also diffuse in the stacks 6₁, 6₂. The diffusion of the Ni atoms is prevented by a plurality of insulating films included in the stacks 6₁, 6₂.

Thus, the gate electrodes 10₁, 10₂ of the MIS transistor composed of the silicide layers 4B₁, 4B₂ and the stacks 6₁, 6₂ can prevent the silicidation of the conductive films on the immediate gate insulating films 2₁, 2₂ of the plurality of conductive films included in the stacks 6₁, 6₂. Therefore, there is no variation in the threshold voltage of the MIS transistor due to the nonuniformity of the silicide layer immediately on the gate insulating film 2.

Thus, there is almost no element-by-element variation in the threshold voltage of the MIS transistor.

The stacks 6₁, 6₂ also include the plurality of insulating films 5A₁, 5B₁, 5A₂, 5B₂, but these films are extremely thin. Therefore, a drive voltage applied to the gate electrodes 10₁, 10₂ of the peripheral transistors is provided between the silicide layers 4B₁, 4B₂ and the polysilicon films 3A₁, 3A₂ formed on the upper surfaces of the gate insulating films 2₁, 2₂ with a small potential drop. Thus, a channel (inversion layer) is formed in the semiconductor substrate 1 immediately under the gate insulating films 2₁, 2₂, so that the operations of the peripheral transistors HVTr, LVTr are not disturbed even if the stacks including the plurality of insulating films are provided on the gate insulating films 2₁, 2₂.

Moreover, in the present embodiment, the stacks 6₁, 6₂ are provided in the gate electrodes 10₁, 10₂ Of the peripheral transistors HVTr, LVTr, such that it is possible to reduce the step between the upper end of the memory cell array region 100 and the upper end of the peripheral circuit region 200 which is produced by the presence of the storage layer and the block insulating film. It is therefore possible to inhibit the difficulty of processing in the manufacturing process from increasing due to the step.

Consequently, according to the manufacturing method of the flash memory in the second embodiment of the present invention, it is possible to provide a flash memory with stabile operation.

(2-2) Manufacturing Method 2

A manufacturing method is described in the case where the sectional structure of the memory cell along the line D-D is as shown in FIG. 13 in the second embodiment of the present invention. Here, the difference between Manufacturing method 2 and Manufacturing method 1 described above is in the manner in which the isolation insulating film 51 is formed.

It should be noted that steps before FIG. 15 are the same as in Manufacturing method 1 and are thus not described.

In the step shown in FIG. 15, for example, after the storage layer in the select gate formation region 10₂ is removed, the intermediate insulating film 2₂ and the first silicon layer 23 are formed in the memory cell array region 100 and the peripheral circuit region 200. Then, the first silicon layer 23, the intermediate insulating film 2₂ and the storage layer 2₁ are selectively removed in the high-breakdown-voltage/low-breakdown-voltage regions 201, 202 by, for example, the photolithographic technique and the RIE method.

Then, trenches are formed in the semiconductor substrate 1 by the photolithographic technique and the RIE method using a resist mask. In addition, a hard mask may be used to form trenches in the semiconductor substrate 1. If the material of the formed hard mask is the same as the material of the storage layer, the hard mask can be removed simultaneously with the storage layer remaining on the stacks 6₁, 6₂. Moreover, the storage layer 2₁ may be used as a hard mask without removing the storage layer 2₁ on the stacks 6₁, 6₂ in the peripheral circuit region 200. Alternatively, the same material as the material of the storage layer 21 may be stacked with a large thickness on the storage layer 21 and used as a hard mask.

Furthermore, the isolation insulating film 51 is embedded into the trenches, so that active regions and isolation regions are formed in the semiconductor substrate 1 within the memory cell array region 100 and the peripheral circuit region 200. Active regions AA in the memory cell array region 100 adjacent in the X-direction are electrically separated by the isolation insulating film 51. The subsequent steps are similar to the steps shown in FIGS. 16 to 19.

The above-described steps enable the memory cell to be formed so that the sectional structure of the memory cell along the line D-D may be as shown in FIG. 13.

(3) Modification

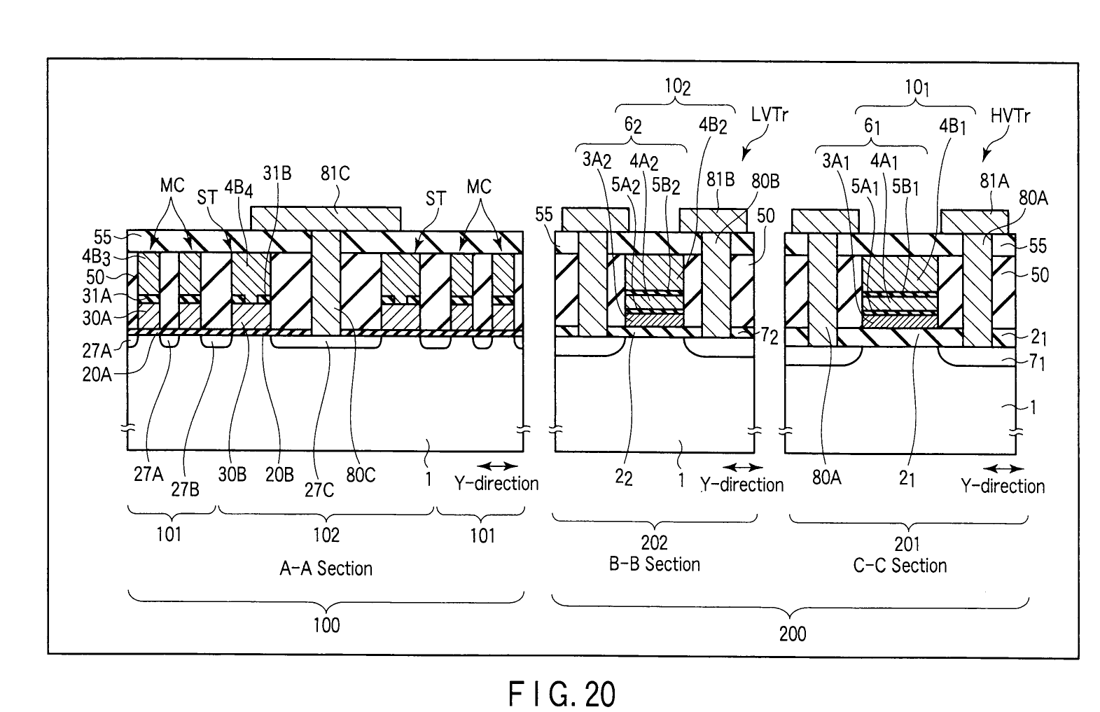

A modification of the flash memory according to the second embodiment of the present invention is described with FIG. 20. It should be noted that the same parts as shown FIGS. 10 to 13 are provided with the same signs and are described in detail when necessary.

The flash memory with memory cells of the MONOS structure has been described in FIGS. 10 to 13. However, the present invention is not limited to this, and may be applied to a flash memory with memory cells of a so-called a stack gate structure which uses a conductive layer (e.g., polysilicon) as a storage layer instead of an insulating layer. In the present modification, the storage layer is referred to as a floating gate electrode 30A.

FIG. 20 shows the sectional structure of the flash memory according to the present modification in the Y-direction (channel length direction).

As shown in FIG. 20, in a memory cell array region 100, a memory cell MC has a stack gate structure in which the floating gate electrode 30A and a control gate electrode 4B₃ are stacked. Specifically, the memory cell MC has a gate structure of the following configuration. The floating gate electrode 30A is provided on a gate insulating film (tunnel insulating film) 20A. The floating gate electrode 30A is made of a semiconductor film, for example, a polysilicon film. A charge is stored in the floating gate electrode 30A, such that data is retained in the memory cell MC.

An intermediate insulating film 31A is provided on the floating gate electrode 30A. The control gate electrode 4B₃ is provided on the intermediate insulating film 31A. The control gate electrode 4B₃ functions as a word line, and has a single-layer structure of a silicide layer (e.g., NiSi₂ layer).

When the memory cell has the floating gate electrode 30A, the gate structure of a select transistor ST has an upper gate electrode 4B₄ stacked on a lower gate electrode 30B which is on a gate insulating film 20B. An insulating film 31B of the same configuration as the intermediate insulating film 31A is interposed between the lower gate electrode 30B and the upper gate electrode 4B₄. An opening is formed in the insulating film 31B, and the lower gate electrode 30B and the upper gate electrode 4B₄ are in direct contact with each other via this opening.

The lower gate electrode 30B is formed simultaneously with the floating gate electrode 30A, and the upper gate electrode 4B₄ is formed simultaneously with the control gate electrode 4B₃. Thus, the upper gate electrode 4B₄ is a silicide layer. In addition, in the select transistor of the present modification, Ni atoms (metal atoms) diffuse into the lower gate electrode 30B via the opening formed in the intermediate insulating film 31B during the formation of the silicide layers 4B₃, 4B₄. However, since the intermediate insulating film 31B is interposed in part, the lower gate electrode 30B does not entirely become a silicide layer.

Furthermore, in the present modification as well, a gate electrode 101 of a high-breakdown-voltage MIS transistor HVTr provided in a peripheral circuit region 200 is composed of a stack 6₁ in which a plurality of conductive films 3A₁, 4A₁ and a plurality of insulating films 5A₁, 5B₁ are alternately stacked, and a silicide layer 4B₁ provided on the stack 6₁. A gate electrode 10₂ of a low-breakdown-voltage MIS transistor LVTr is similarly composed of a stack 6₂ and a silicide layer 4B₂.

In the stacks 6₁, 6₂, the conductive films 3A₁, 3A₂ on the immediate gate insulating films 2₁, 2₂ are made of a conductive material (e.g., polysilicon) different from that of the silicide layers 4B₁, 4B₂.

It is thus possible to obtain effects similar to the effects of the peripheral transistors provided in the flash memory shown in FIGS. 10 to 13, and there is no variation in the threshold voltage of the MIS transistor due to nonuniformity in the silicide layers 4B₁, 4B₂.

Consequently, according to the modification of the second embodiment of the present invention, it is also possible to stabilize the operation of the MIS transistor (peripheral transistor).

In addition, the manufacturing method of the flash memory in the present modification shown in FIG. 20 is basically the same as the manufacturing process described with FIGS. 14 to 20, but different therefrom in the following respects.

After the stacks composed of the plurality of conductive films and the plurality of insulating films are formed on the gate insulating films 2₁, 2₂ in the peripheral region 200 (see FIG. 14), the stack and the insulating film formed in the memory cell array region 100 are removed. As in the step shown in FIG. 15, gate insulating films 20A, 20B are formed on the surface of a semiconductor substrate 1 in the memory cell array region 100.

Subsequently, instead of an insulating film as a storage layer, for example, a polysilicon film 30A serving as the floating gate electrode 30A is formed on the gate insulating films 20A, 20B. Then, the intermediate insulating films 31A, 31B are formed on the polysilicon film 30A. At the same time, an opening is formed in the intermediate insulating film 31B in the select gate formation region 102.

Furthermore, a first silicon layer is formed on the intermediate insulating film by steps similar to the steps shown in FIGS. 16 to 19. Then, a gate fabrication step and a source/drain diffusion layer forming step are performed, so that an insulating layer 50 is formed.

For example, after a second silicon layer is formed, a metal film is formed, and silicidation processing (solid-phase reaction) is carried out. The silicide layers 4B₁, 4B₂, 4B₃, 4B₄ are formed by the silicidation processing, and then an insulating layer 55 and contacts 80A, 80B, 80C and interconnect layers 81A, 81B, 81C are formed, such that the flash memory in the present modification is completed.

Even when a memory cell with a floating gate electrode is used, the gate electrode (control gate electrode) of the memory cell has a FUSI structure in the flash memory in the present modification, and the gate electrodes 10₁, 10₂ of the peripheral transistors HVTr, LVTr include no silicide films on the immediate gate insulating films 2₁, 2₂. That is, in the gate electrodes 10₁, 10₂ of the peripheral transistors HVTr, LVTr, conductive films made of a material (e.g., polysilicon) different from silicide are in direct contact with the gate insulating films 2₁, 2₂.

The flash memory according to the modification of the second embodiment of the present invention can be manufactured by the manufacturing process described above.

Consequently, according to the modification of the second embodiment of the present invention, it is also possible to provide a flash memory capable of stabile operation.

2. Others

According to the first and second embodiments of the present invention, it is possible to stabilize the operation of the MIS transistor.

In addition, the flash memory has been described as an example in the second embodiment of the present invention. However, the present invention may also be applied to a peripheral transistor (MIS transistor) used in, for example, a magnetoresistive random access memory (MRAM), a phase change random access memory (PCRAM) or a resistance random access memory (ReRAM). In such a case as well, effects similar to the effects in the embodiments of the present invention are obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
two diffusion layers provided in the semiconductor substrate;
a gate insulating film provided on a channel region between the two diffusion layers; and
a gate electrode which is composed of a stack of a plurality of conductive films and a plurality of insulating films provided on the gate insulating film and a silicide layer provided on the stack,
wherein of the plurality of films included in the stack, the conductive film different in configuration from the silicide layer is in contact with the gate insulating film.

2. The semiconductor device according to claim 1, wherein
the plurality of conductive films and the plurality of insulating films are alternately stacked in the stack.

3. The semiconductor device according to claim 1, wherein
the number of metal atoms derived from the silicide layer and contained in the conductive film on the side of the gate insulating film of the plurality of conductive films constituting the stack is equal to or smaller than the number of metal atoms derived from the silicide layer and contained in the conductive film on the side of the gate electrode.

4. The semiconductor device according to claim 2, wherein
a silicon film is used for the conductive film in direct contact with the gate insulating film, and a silicon substrate is used for the semiconductor substrate.

5. A manufacturing method of a semiconductor device comprising:
forming a gate insulating film on a semiconductor substrate;
forming a stack of a plurality of conductive films and a plurality of insulating films on the gate insulating film;
forming a silicon layer on the stack;
etching the silicon layer and the stack to gate electrode fabrication;
forming a diffusion layer in the semiconductor substrate after the gate electrode fabrication;
forming a metal film on the silicon layer; and
forming a silicide layer on the stack by a solid-phase reaction between the silicon layer and the metal film so that the conductive film in contact with the gate insulating film of the plurality of conductive films included in the stack is not silicided.

6. The method according to claim 5, wherein
the plurality of conductive films and the plurality of insulating films are alternately stacked to form the stack.

7. The method according to claim 5, wherein
the number of metal atoms derived from the metal film and contained in the conductive film on the side of the gate insulating film of the plurality of conductive films constituting the stack is equal to or smaller than the number of metal atoms derived from the metal film and contained in the conductive film on the side of the gate electrode, after the formation of the silicide layer.

8. The method according to claim 5, wherein
a silicon film is used for the conductive film in direct contact with the gate insulating film, and a silicon substrate is used for the semiconductor substrate.

9. A semiconductor device comprising:
a semiconductor substrate;
a memory cell array region provided in the semiconductor substrate;
a memory cell having two first diffusion layers which are provided in the semiconductor substrate within the memory cell array region, a tunnel insulating film provided on a channel region between the first diffusion layers, a storage layer provided on the tunnel insulating film, an intermediate insulating layer provided on the storage layer, and a first gate electrode which is provided on the intermediate insulating layer and which is formed of a first silicide layer;
a peripheral circuit region provided in the semiconductor substrate adjacently to the memory cell array region; and
a peripheral transistor having two second diffusion layers provided in the semiconductor substrate within the peripheral circuit region, a gate insulating film provided on a channel region between the second diffusion layers, and a second gate electrode which is composed of a stack of a plurality of conductive films and a plurality of insulating films provided on the gate insulating film and a second silicide layer provided on the stack,
wherein the conductive film different in configuration from the second silicide layer of the plurality of conductive films included in the stack is in contact with the gate insulating film.

10. The semiconductor device according to claim 9, wherein
the plurality of conductive films and the plurality of insulating films are alternately stacked in the stack.

11. The semiconductor device according to claim 9, wherein
the number of metal atoms derived from the second silicide layer and contained in the conductive film on the side of the gate insulating film of the plurality of conductive films constituting the stack is equal to or smaller than the number of metal atoms derived from the second silicide layer and contained in the conductive film on the side of the gate electrode.

12. The semiconductor device according to claim 9, wherein
the conductive film in direct contact with the gate insulating film is a silicon film, and the semiconductor substrate is a silicon substrate.

13. The semiconductor device according to claim 9, wherein
the thickness of each of the plurality of insulating films is smaller than the thickness of the tunnel insulating film.

14. The semiconductor device according to claim 9, wherein
the storage layer is an insulating film containing a charge trapping level.

15. The semiconductor device according to claim 9, wherein
the storage layer is a semiconductor film.
